(19) United States
(12) Patent Application Publication
(10) Pub. No.: US 2020/0326569 A1
(43) Pub. Date: Oct. 15, 2020

(54) ARRAY SUBSTRATE, METHOD FOR MANUFACTURING THE SAME, DISPLAY PANEL, AND DISPLAY DEVICE

(71) Applicant: BOE TECHNOLOGY GROUP CO., LTD., Beijing (CN)

(72) Inventors: Haixu Li, Beijing (CN); Zhanfeng Cao, Beijing (CN); Qi Yao, Beijing (CN); Jianguo Wang, Beijing (CN); Da Lu, Beijing (CN); Shuilang Dong, Beijing (CN); Qingzhao Liu, Beijing (CN); Shengguang Ban, Beijing (CN)

(21) Appl. No.: 16/097,764

(22) PCT Filed: Mar. 30, 2018
(86) PCT No.: PCT/CN2018/081218

§ 371 Date: Oct. 30, 2018

(30) Foreign Application Priority Data
May 24, 2017 (CN) 201710375613.7

(51) Int. Cl. G02F 1/1368; G02F 1/1362; H01L 27/12

(52) U.S. Cl. CPC G02F 1/1368; G02F 1/136209; G02F 2001/13685; H01L 27/127; H01L 27/1262

(57) ABSTRACT

An array substrate, a method for manufacturing the same, a display panel, and a display device are provided. The array substrate comprises a substrate, a light shielding layer on the substrate, and a transistor arranged at a side of the light shielding layer away from the substrate, the transistor including an active layer.

### RELATED APPLICATION

The present application claims the benefit of Chinese Patent Application No. 201710375613.7, filed on May 24, 2017, the entire disclosure of which is incorporated herein by reference.

### TECHNICAL FIELD

The present disclosure generally relates to the field of display technologies, and specifically to an array substrate, a method for manufacturing the same, a display panel and a display device.

### BACKGROUND

With the development of semiconductor technologies in recent years, display devices like liquid crystal displays are more and more widely used in various electronic apparatuses. But at the same time, users' requirements on the performance of the display device (e.g. the resolution, contrast, etc. of the display device) also become higher and higher. To meet such requirements and to further improve the performance of the display device, the low temperature polysilicon (LTPS) has been universally used in display panels. The LTPS is a kind of semiconductor material with high mobility, and by using it to prepare the array substrate of the Thin Film Transistor Liquid Crystal Display (TFT-LCD), for example, forming the active layer of the thin film transistor in the array substrate, the response time of the thin film transistor can be shortened, the power consumption of the array substrate and the display panel can be reduced and the resolution and contrast of the display device can be increased.

However, currently, the array substrate and its manufacturing method, the display panel and display device still need to be improved.

### SUMMARY

According to an aspect of the disclosure, there is provided an array substrate, comprising a substrate, a light shielding layer on the substrate; and a transistor arranged at a side of the light shielding layer away from the substrate, the transistor including an active layer.

According to some embodiments of the disclosure, the light shielding layer comprises a Ge-doped amorphous silicon.

According to some embodiments of the disclosure, the active layer comprises a low temperature polysilicon.

According to some embodiments of the disclosure, the array substrate further comprises a first buffer layer between the active layer and the light shielding layer.

According to some embodiments of the disclosure, the transistor further comprises a source and a drain arranged at a side of the active layer away from the first buffer layer, and the source and drain being located at either sides of a channel region in the active layer, respectively; and a gate whose orthographic projection on the substrate at least partially overlaps that of the channel region on the substrate.

According to some embodiments of the disclosure, a content of Ge in the light shielding layer is 0.5-5 wt %, which is dependent on a total mass of the light shielding layer.

According to some embodiments of the disclosure, the array substrate further comprises a second buffer layer between the light shielding layer and the substrate.

According to some embodiments of the disclosure, the orthographic projection of the light shielding layer on the substrate covers that of the active layer on the substrate.

According to some embodiments of the disclosure, the first buffer layer comprises SiO₂.

According to some embodiments of the disclosure, the second buffer layer comprises SiNₓ.

According to another aspect of the disclosure, there is provided a display panel comprising any of the array substrates as described above.

According to a further aspect of the disclosure, there is provided a display device comprising the display panel as described above.

According to yet another aspect of the disclosure, there is provided a method for manufacturing an array substrate, comprising: providing a light shielding layer on a substrate, and providing a transistor on a side of the light shielding layer away from the substrate, the transistor comprising an active layer.

According to some embodiments of the disclosure, the light shielding layer is made from a Ge-doped amorphous silicon.

According to some embodiments of the disclosure, the active layer is made from a low temperature polysilicon, and the method further comprises providing a first buffer layer between the light shielding layer and the active layer.

According to some embodiments of the disclosure, the active layer is formed by the steps of forming an amorphous silicon layer through chemical vapor deposition; and performing laser annealing to the amorphous silicon layer, thereby forming the active layer.

According to some embodiments of the disclosure, a content of Ge in the light shielding layer is 0.5-5 wt %, which is dependent on a total mass of the light shielding layer.

According to some embodiments of the disclosure, the light shielding layer is formed by the steps of forming an amorphous silicon material layer through chemical vapor deposition, and adding Ge source gas while performing the chemical vapor deposition.

According to some embodiments of the disclosure, the light shielding layer is formed by the steps of forming an amorphous silicon material layer through chemical vapor deposition, and doping Ge into the amorphous silicon material layer through ion implantation.

According to some embodiments of the disclosure, the method further comprises providing a second buffer layer on the substrate before providing the light shielding layer.

According to some embodiments of the disclosure, the above-described method further comprises providing a source and a drain at a side of the active layer away from the substrate, the source and drain being located at both sides of a channel region in the active layer, respectively; and providing a gate at the side of the active layer away from the substrate, an orthographic projection of the gate on the substrate at least partially overlapping that of the channel region on the substrate.

### BRIEF DESCRIPTION OF THE DRAWINGS

The above and/or additional aspects and advantages of the present disclosure will become apparent and easily understandable from descriptions of the embodiments given with reference to the following drawings, in which,

FIG. 1 is a structural diagram of an array substrate according to an embodiment of the disclosure;

FIG. 2 is a structural diagram of an array substrate according to another embodiment of the disclosure;

FIG. 3 is a structural diagram of a display panel according to an embodiment of the disclosure;

FIG. 4 is a structural diagram of a display device according to an embodiment of the disclosure;

FIG. 5 is a part of a flow chart of a method for manufacturing an array substrate according to an embodiment of the disclosure;

FIG. 6 is a flow chart of a method for manufacturing an array substrate according to another embodiment of the disclosure;

FIG. 7A and FIG. 7B are flow charts of a method for manufacturing an array substrate according to an embodiment of the disclosure;

FIG. 8 is a part of a flow chart of a method for manufacturing an array substrate according to another embodiment of the disclosure.

### DETAILED DESCRIPTION OF EMBODIMENTS

Embodiments of the disclosure will be described in detail below, and examples of the embodiments are shown in the drawings, in which the same or similar numerals are used to indicate the same or similar elements or elements having the same or similar functions. The embodiments described below with reference to the drawings are exemplary, they only intend to explain the present disclosure but cannot be construed as limiting the scope of the disclosure.

In the drawings, the following reference numerals are used:

100: substrate; 210: light shielding layer; 211: Ge-doped amorphous silicon layer; 212: first amorphous silicon layer; 220: active layer; 221: amorphous silicon layer; 222: polysilicon layer; 223: second amorphous silicon layer; 230: gate; 241: source; 242: drain; 250: first buffer layer; 251: silicon oxide layer; 300: second buffer layer; 400: gate insulating layer: 500: interlayer dielectric layer; 1000: display panel; 1100: display device.

Inventors of the disclosure found that in the current liquid crystal display devices using LTPS as the material of the active layers, the problem that the array substrate cannot well control the liquid crystal layer prevails. After making thorough researches and lots of experiments, the inventors found that this problem is mainly caused by the high photosensitivity of the LTPS material, i.e. when the backlight passes through the active layer formed by the LTPS, the LTPS material tends to generate photoelectrons, thus influencing the characteristics of TFT containing the LTPS and causing an unstable threshold voltage (Vₜₕ) and an increased off-state current (I_{off}), which in turn results in a decreased switching ratio of the TFT device. In order to overcome this problem, a light shielding layer may be formed at the bottom of the LTPS layer when fabricating the active layer with the LTPS material, thereby preventing the active layer from generating photocurrent with irradiation of the backlight. The light shielding layer may be made of a metal material or silicon. However, in case the light shielding layer is formed of silicon, because of the characteristics of the silicon material, about 30-70% of the high wavelength visible light (e.g., red light, green light) still transmits, which will result in generation of the photoelectrons in the LTPS layer. When the light shielding layer is made of the metal material, although a good light shielding effect can be achieved, charge accumulation at the light shielding layer tends to occur due to the metal material, thereby influencing the electrical performance of the array substrate. Therefore, if the light shielding effect of the light shielding layer can be enhanced without influencing the electrical performance of the array substrate itself, the display performance of the LTPS-based display device will be greatly improved.

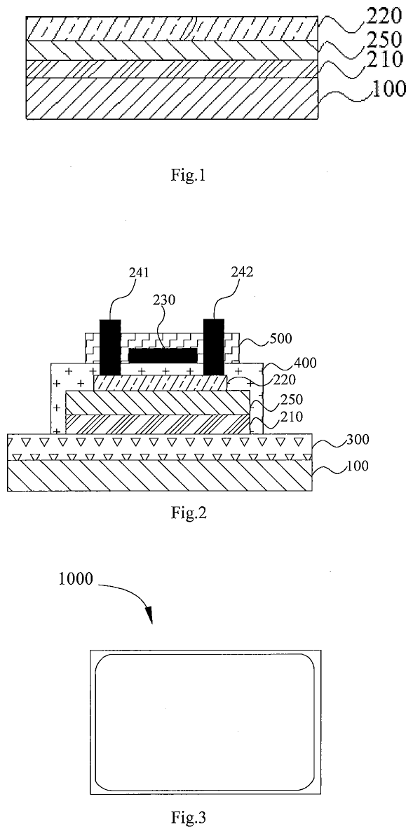

In an aspect, an embodiment of the present disclosure proposes an array substrate, as shown in FIG. 1, which comprises a substrate 100, a light shielding layer 210 on the substrate 100, and a transistor arranged at a side of the light shielding layer 210 away from the substrate 100. The transistor includes an active layer 220. According to the embodiment of the disclosure, the light shielding layer 210 is arranged on the substrate 100 and particularly contains Ge-doped amorphous silicon. The active layer 220 is arranged at the side of the light shielding layer 210 away from the substrate 100. Thus, the light shielding layer 210 can prevent the active layer 220 from generating a leakage current when being irradiated by light, as a result, the performance of the array substrate can be improved. It shall be noted that the transistor may further include such necessary structures as a source, a drain, a gate, etc. (not shown in the figure). In the present disclosure, the structures, materials, specific shapes and thicknesses of the gate, source and drain are not limited in any particular way, and they can be designed by those skilled in the art as needed. For example, referring to FIG. 2, the transistor can be a top gate transistor. That is, a gate 230 is arranged at the top of the transistor furthest away from the substrate 100 and is corresponding to a channel region in the active layer 220, in other words, an orthographic projection of the gate 230 on the substrate 100 at least partially overlaps an orthographic projection of the channel region on the substrate 100. A source 241 and a drain 242 are arranged at either sides of the channel region, respectively. However, those skilled in the art shall appreciate that the inventive concepts revealed in the disclosure are also applicable to transistors of other structures, such as a bottom gate transistor, and the like.

Respective components of the array substrate will be described in detail below in conjunction with specific embodiments of the disclosure.

According to the embodiments of the disclosure, the specific material for forming the substrate 100 is not limited in any particular way, and those skilled in the art can choose as desired, as long as the material has a certain mechanical strength so as to provide sufficient support for other structures of the array substrate.

According to an embodiment of the disclosure, the material for forming the active layer 220 is not limited in any particular way, and those skilled in the art can determine according to the actual need, as long as it can realize the function of the transistor. For example, according to an embodiment, the active layer 220 is made of polysilicon. More specifically, the active layer 220 can be formed of the LTPS. At least one of the following advantages can be achieved by using the LTPS to form the active layer 220: a high electron mobility resulted from the LTPS; the LTPS technology has significant advantages in terms of element miniaturization, increasing an aperture ratio, and improving image quality and sharpness; and compared to the conventional Thin Film Transistor Liquid Crystal Display (TFT-LCD) formed with amorphous silicon material, the thin film transistor made of the LTPS material (i.e the active layer being formed of the LTPS) has a faster reaction speed, which helps to enhance control to the liquid crystal molecules and to reduce the size of the array substrate. In summary, by using the LTPS material to form the active layer 220, the transistor formed can be miniaturized on the one hand so as to increase the aperture ratio of the liquid crystal display, thus a better display brightness and a better color can be presented with the same power supplied by the backlight module. On the other hand, using the LTPS to form the active layer 220 can decrease the power consumption of the array substrate. Thus by means of the excellent performance of the LTPS material, the performance of the array substrate can be further improved.

According to an embodiment of the present disclosure, as mentioned above, since the polysilicon material is high photosensitive, when the active layer 220 is formed by polysilicon, the light shielding layer 210 needs to be provided so as to prevent the active layer 220 from generating a leakage current while irradiated by the backlight. Particularly, when the LTPS material is used for forming the active layer 220, the leakage current generated by the active layer 220 under light irradiation is ten times or even a hundredfold of that generated by the active layer formed by amorphous silicon. On the other hand, as can be appreciated by those skilled in the art, in the liquid crystal display device, light generated by the backlight module needs to transmit through the array substrate and irradiate on the liquid crystal layer so as to be deflected by the liquid crystals and finally exit from one side of the color film substrate, thereby to realize a normal display function of the display device. That is to say, the active layer 220 of the array substrate must be exposed to light irradiation when the display device is in operation. Therefore, if the light-induced leakage current generated by the active layer 220 cannot be effectively controlled, the array substrate would be unable to effectively control deflection of the liquid crystal molecules, and the normal display will be influenced. According to an embodiment of the disclosure, by providing the light shielding layer 210 between the substrate 100 and the active layer 220, the backlight generated by the backlight module can be enabled to penetrate through the substrate 100 so as to irradiate on the light shielding layer 210 instead of the active layer 220. Thus the active layer 220 of the array substrate is prevented from being exposed in the backlight environment during the operation of the display device, thereby mitigating or reducing generation of the leakage current.

According to an embodiment of the present disclosure, the light shielding layer 210 is formed of amorphous silicon. The inventors found through a lot of experiments that compared to the polysilicon, the amorphous silicon is much less sensitive to light. In other words, under light irradiation, the amorphous silicon material almost generates no light-induced carrier. Besides, the amorphous silicon material can better absorb visible light, so it can be used for forming the light shielding layer 210 of the array substrate. Moreover, compared to the light shielding layer formed by metal materials, the light shielding layer 210 formed by the amorphous silicon will not cause charge accumulation, so it can be more widely used in array substrates without adversely influencing the electrical performances of the transistors.

According to an embodiment of the present disclosure, in order to further improve the light shielding effect of the light shielding layer 210, the light shielding layer 210 is made from Ge-doped amorphous silicon. The inventors found after an in-depth study that absorption to high wavelength visible light (red light, green light) can be increased after doping Ge atoms into the amorphous silicon, as a result, the light shielding effect of the light shielding layer can be further improved.

The inventors also found that, the number of valence electrons of Ge (4s²4p²) is the same as the number of valence electrons of Si(3s²3p²), but after doping Ge into the amorphous silicon, so that Ge occupies the position of the Si atom in the polysilicon, i.e., a replacement-type doping (replacing Si with Ge) is accomplished, the bottom of conduction band of the Ge-doped amorphous silicon moves towards a low energy direction since Ge has a lower electronegativity than Si. At the same time, the top of valence band remains unchanged, which is depending on Si, so the band gap will decrease overall. As the Ge atoms replacing the Si atoms increase in number, the position of the bottom of conduction band changes gradually from being dependent on the 3p-state electrons of Si into being dependent on the 4p-state electrons of Ge. Thus the larger the number of the Ge atoms that replace the Si atoms, the more obvious the change of the position of the bottom of conduction band, and the smaller the band gap. Therefore, after doping Ge into the amorphous silicon, the absorption edge and absorption peak thereof will move towards the low energy direction, i.e. a red shift occurs, thereby enhancing absorption of red light. On the other hand, the atomic radius of Ge is generally 0.152 nm, which is greater than the lattice constant (0.146 nm) of Si, so the doping of Ge will increase both the lattice constant and volume of the unit cell; meanwhile, since Ge has a weaker electronegativity than Si, when replacing the Si atoms to form covalent bonds, most electrons will be confined on the Si atoms, resulting in an increased lattice constant. Thus, after doping Ge, surface roughness of the amorphous silicon increases, which enhances light scattering and further decreases the intensity of light impinging the LTPS active layer. In summary, the Ge-doped amorphous silicon has a higher absorbility for red light of the backlight and enhances scattering of light, so the light shielding capability of the light shielding layer can be remarkably enhanced and the performance of the display device can be further improved accordingly.

According to an embodiment of the present disclosure, depending on the total mass of the light shielding layer 210, the content of Ge can be 0.5-5 wt %. In this case, the light shielding performance of the light shielding layer can be further improved.

According to an embodiment of the disclosure, the orthographic projection of the active layer 220 on the substrate 100 is included in the orthographic projection of the light shielding layer 210 on the substrate 100. That is to say, a surface of the active layer 220 close to the light shielding layer 210 is completely blocked by the light shielding layer 210, thus the light shielding performance of the light shielding layer 210 can be improved and the performance of the array substrate can be further improved.

According to an embodiment of the present disclosure, if the light shielding layer 210 is formed from amorphous silicon, and the active layer 220 is formed from polysilicon, in order to avoid mutual influence between the light shielding layer 210 and the active layer 220 caused by direct contact of the two layers, a buffer structure may be provided between the light shielding layer 210 and the active layer 220. According to an embodiment of the disclosure, as shown in FIG. 1, a first buffer layer 250 may be provided between the light shielding layer 210 and the active layer 220. According to an embodiment of the disclosure, the specific material of the first buffer layer 250 is not particularly limited, as long as it can prevent atoms in the light shielding layer 210 from entering into the structure (e.g. the active layer 220) above the first buffer layer 250. For example, the first buffer layer 250 can be made from SiO₂. When the first buffer layer 250 is made from SiO₂, the first buffer layer 250 can be conveniently formed by oxidizing a portion of the light shielding layer 210, so the preparation process can be simplified and the preparation cost can be reduced.

It shall be noted that the transistor according to the embodiment of the disclosure may also have such necessary structures as an insulating layer, a dielectric layer, etc. in addition to the above-described structures, so as to realize insulation between electrodes (e.g. gate 230, source 241 and drain 242) and the active layer 220 and insulation between the source 241 and the drain 242.

According to a specific embodiment of the disclosure, as shown in FIG. 2, the array substrate further comprises a second buffer layer 300. According to a specific embodiment of the disclosure, the second buffer layer 300 is arranged between the substrate 100 and the light shielding layer 210, thereby further improving the performance of the array substrate. According to an embodiment, the specific material for forming the second buffer layer 300 is not particularly limited, as long as it can prevent atoms in the underneath substrate from entering into the structure above the second buffer layer 30. For example, the material of the second buffer layer 300 can be SiNₓ. Thus it can prevent atoms in the substrate 100 (e.g. glass) from entering into the light shielding layer 210 to influence the electrical performance of the transistor. SiNₓ can be conveniently formed by nitriding the silicon material, so forming the second buffer layer 300 of SiNₓ can simplify the preparation process and reduce the preparation cost.

According to a specific embodiment of the disclosure, the array substrate may further comprise a gate insulating layer 400 and an interlayer dielectric layer 500. As shown in FIG. 2, the gate insulating layer 400 may be provided between the gate 230 and the active layer 220 to cover the transistor. The interlayer dielectric layer 500 may be provided between the gate 230, and the source 241 and drain 242 while covering the gate 230. According to an embodiment of the disclosure, the specific materials for forming the gate insulating layer 400 and the interlayer dielectric layer 500 are not particularly limited, and those skilled in the art can choose appropriate materials according to actual needs. For example, the gate insulating layer 400 can be made from SiNₓ and the interlayer dielectric layer 500 can also be made from SiNₓ.

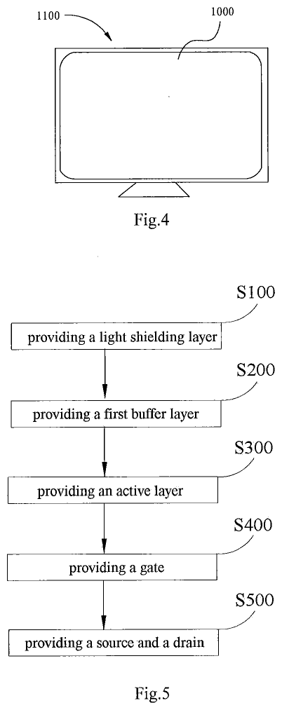

According to another aspect, referring to FIG. 3, an embodiment of the present disclosure proposes a display panel 1000, which comprises any one of the above-described array substrates. Thus the display panel 1000 has all the features and advantages of the above-described array substrates, which will not be reiterated herein any more. Generally speaking, the display panel has at least one of the advantages of low light-induced leakage current generated by the array substrate, better control to the liquid crystal molecules, etc.

According to still another aspect, referring to FIG. 4, an embodiment of the disclosure proposes a display device 1100, which comprises the above-described display panel 1000. Thus the display device 1100 has all the features and advantages of the above-described display panel 1000, which will not be reiterated herein any more. Generally speaking, the display device has at least one of the advantages of low photo-induced leakage current generated by the array substrate and better control to the liquid crystal molecules, etc.

According to a further aspect of the disclosure, an embodiment of the disclosure proposes a method for manufacturing any one of the above-described array substrates. According to the embodiment of the disclosure, the array substrate manufactured by this method may have the same features and advantages as the above-described array substrates. According to an embodiment, the method comprises arranging a light shielding layer on the substrate and arranging a transistor at a side of the light shielding layer away from the substrate.

FIG. 5 shows a flow chart of a method for manufacturing an array substrate according to an embodiment of the disclosure.

As shown in FIG. 5, at step S100, a light shielding layer is arranged on a substrate.

According to an embodiment, in this step, the light shielding layer on the substrate may be formed of amorphous silicon. According to the embodiment of the disclosure, the light shielding layer formed in this step may have the same features and advantages as the previously described light shielding layer in the array substrate.

In order to further improve the performance of the array substrate, to according to an embodiment of the disclosure, the light shielding layer may be formed from Ge-doped amorphous silicon. According to an embodiment of the disclosure, the specific content of Ge doped is not particularly limited, and those skilled in the art can choose as desired. For example, according to a specific embodiment, depending on the total mass of the light shielding layer, the content of Ge can be 0.5-5 wt %. The Ge-doped amorphous silicon has stronger absorbility for the red portion in the backlight, thus it can further enhance the light shielding capability of the light shielding layer and improve the performance of the display device.

The inventors found after implementing lots of experiments that when the content of Ge doped in the light shielding layer is too low, absorption of high wavelength visible light by the amorphous silicon cannot be effectively improved; if the doping content of Ge is too high, the manufacturing cost will be increased, and the electrical and optical performances of the light shielding layer will be significant affected as well, as a result, the electrical performance of the transistor might be adversely affected.

Still referring to FIG. 5, at step S200, a first buffer layer is provided.

According to an embodiment of the disclosure, in order to avoid mutual influence between the subsequently formed active layer (which may be formed from polysilicon, e.g.) and the light shielding layer formed from amorphous silicon, a first buffer layer may be arranged on the light shielding layer before forming the active layer. Thus atoms in the light shielding layer can be prevented from entering into the active layer. According to an embodiment of the disclosure, the specific material for the first buffer layer is not particularly limited, as long as it can function to block as described above. For example, according to an embodiment of the disclosure, the first buffer layer may be formed from SiO₂. Thus the performance of the array substrate can be further improved.

It shall be noted that the step S200 of forming the first buffer layer is optional. In some embodiments, step S200 can be omitted. For example, in embodiments where the material forming the active layer and the material forming the light shielding layer do not influence each other, the first buffer layer can be omitted.

Still referring to FIG. 5, at step S300, an active layer is formed.

According to an embodiment, if the first buffer layer is provided, the active layer is arranged at a side of the first buffer layer away from the light shielding layer. When no first buffer layer exists, the active layer is arranged at a side of the light shielding layer away from the substrate. According to an embodiment of the disclosure, the active layer formed in this step may have the same features and advantages as the previously described active layer of the array substrate. For example, according to a specific embodiment, the active layer may comprise low temperature polysilicon. As for the advantages of using polysilicon, especially low temperature polysilicon to form the active layer, they have been explained in the text above and will not be elaborated herein any more.

According to an embodiment of the disclosure, the specific steps of forming the active layer are not particularly limited, and those skilled in the art may use any appropriate method to form the active layer. For example, according to an embodiment of the disclosure, the active layer may be formed by the following steps: first an amorphous silicon layer is formed by chemical vapor deposition; next, laser annealing is performed to the amorphous silicon layer to convert the amorphous silicon into polysilicon so as to form the active layer. In this way, the active layer can be easily fabricated and the performance of the array substrate can be further improved.

Still referring to FIG. 5, at step S400, a gate is provided.

According to an embodiment of the present disclosure, in this step, a gate is provided so as to realize electrical functions of the transistor. According to an embodiment of the disclosure, the specific position and arrangement of the gate are not particularly limited, and those skilled in the art may determine according to the actual situation. For example, the gate may be arranged at the top of the transistor to be corresponding to a channel region in the active layer, and the source and drain are arranged at either sides of the channel region, respectively (i.e the transistor is a top gate transistor). That is, the gate formed in this step is corresponding to the active layer. In other words, the gate formed in this step can control semiconductor materials (e.g. low temperature polysilicon) in the active layer by applying gate voltages. According to an embodiment of the disclosure, the composition material, specific shape and thickness of the gate are not limited particularly, and those skilled in the art can make adjustment according to the actual situation.

It shall be pointed out that the principle of the disclosure also is applicable to transistors of other structures, such as a bottom gate transistor, etc.

Still referring to FIG. 5, at step S500, a source and a drain are formed.

According to an embodiment of the disclosure, in this step, a source and a drain are formed so as to achieve electrical functions of the transistor. Specifically, the source and drain can be arranged on the active layer. According to the embodiment of the disclosure, the structures, composition materials, specific shapes and thicknesses of the source and drain are not limited particularly, and those skilled in the art can make adjustment according to actual situations.

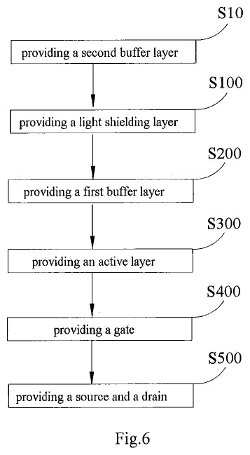

FIG. 6 shows a flow chart of a method for manufacturing an array substrate according to another embodiment of the disclosure. Compared to FIG. 5, FIG. 6 differs by further including providing a second buffer layer at step S10.

According to an embodiment of the disclosure, in this step, before arranging the transistor, i.e. before forming the light shielding layer, a second buffer layer may be arranged on the substrate, so that atoms in the substrate can be prevented from entering into the light shielding layer, thus the performance of the array substrate can be further improved. According to an embodiment of the present disclosure, the specific material for forming the second buffer layer is not particularly limited, as long as it can prevent atoms in the substrate from entering into the light shielding layer. For example, the second buffer layer may comprise SiNₓ. Thus atoms in the substrate (e.g. glass) can be prevented from entering into (the light shielding layer of) the transistor to influence the electrical performance of the transistor.

It shall be noted that although FIG. 5 and FIG. 6 describe and illustrate in a specific order the method for manufacturing an array substrate according to the embodiments of the present disclosure, the embodiments of the disclosure are not so limited, and other feasible orders can also be possible. For example, some steps can be performed concurrently or in an opposite order.

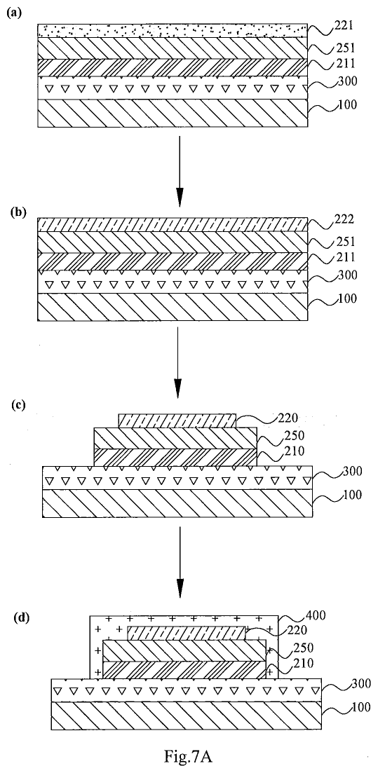

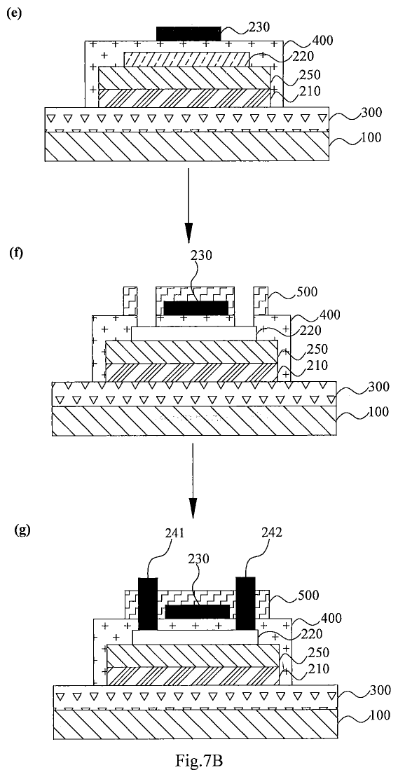

FIGS. 7A-7B schematically show processes of manufacturing an array substrate according to an embodiment of the disclosure. As shown in (a) in FIG. 7A, a second buffer layer 300, a Ge-doped amorphous silicon layer 211, a silicon oxide layer 251 and an amorphous silicon layer 221 are formed sequentially on the substrate by means of chemical vapor deposition. The Ge-doped amorphous silicon layer 211 can be subjected to a subsequent etching process to form the light shielding layer. The Ge-doped amorphous silicon layer 211 can be formed by adding Ge source gas during the chemical vapor deposition. Thus deposition of the amorphous silicon and doping of Ge can be accomplished by one time chemical vapor deposition, so that operation steps of the method are further simplified.

According to an embodiment of the present disclosure, the added Ge source gas can be GeH₄. Thus Ge can be easily doped into amorphous silicon to replace the position of Si atom, thereby forming Ge-doped amorphous silicon layer 211. The inventors found that when the light shielding layer is formed from Ge-doped amorphous silicon, absorption of the backlight by the light shielding layer can be increased. Specifically, when the backlight is incident onto the light shielding layer, transmittance of light (e.g., red, green) having long wavelength of the backlight decreases. Depending on different amounts of doped Ge, transmittance of light having long wave length through the light shielding layer may decrease to 10-50% (which is about 30%-70% in case no Ge is doped).

The amorphous silicon layer 221 can be used to form the active layer. Specifically, referring to (b) in FIG. 7A, the amorphous silicon layer 221 is subjected to laser annealing so as to convert it into a polysilicon layer 222. Then, referring to (c) in FIG. 7A, the Ge-doped amorphous silicon layer 211, the oxide silicon layer 251 and the polysilicon layer 222 are etched to form the light shielding layer 210, the first buffer layer 250 and the active layer 220. Since the active layer is obtained by converting amorphous silicon into polysilicon, if no first buffer layer 300 exists between the active layer and the light shielding layer, when laser annealing is performed, the amorphous silicon for forming the light shielding layer 211 will also be converted into polysilicon and thus losing the light shielding function.

According to an embodiment of the disclosure, the specific way of the etching process is not particularly limited, for example, it can be an etching process using a mask. According to an embodiment of the disclosure, after etching, the orthographic projection of the light shielding layer 210 on the substrate 100 may include the orthographic projection of the active layer 200 on the substrate 100. In this way, the light shielding effect of the light shielding layer 210 can be further improved.

After forming the light shielding layer and the active layer, referring to (d) in FIG. 7A, deposition of a gate insulating layer 400 can be performed. According to an embodiment of the present disclosure, the deposition thickness can be 500-1500 Å, and the deposited material can be SiNₓ. Then referring to (e) in FIG. 7B, deposition of the gate 230 is performed.

After forming the gate 230, referring to (f) in FIG. 7B, deposition and patterning (for forming holes) of the interlayer dielectric layer 500 may be performed. Finally, referring to (g) in FIG. 7B, deposition and patterning of the source 241 and drain 242 are performed so as to obtain the array substrate according to the embodiments of the present disclosure.

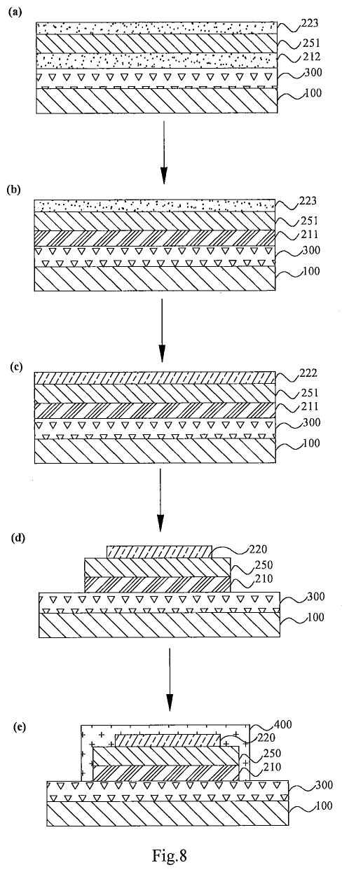

It shall be noted that FIGS. 7A-7B take the top gate transistor as an example to illustrate the method for manufacturing an array substrate according to the embodiment of the present disclosure, but the inventive concept of the disclosure is also applicable to transistors of other structures, such as a bottom gate transistor. FIG. 8 schematically shows a portion of a process for manufacturing an array substrate according to another embodiment of the disclosure. Referring to (a) in FIG. 8, a second buffer layer 300, a first amorphous silicon layer 212, a silicon oxide layer 251 and a second amorphous silicon layer 223 are formed sequentially on the substrate by means of chemical vapor deposition. The first amorphous silicon layer 212 can be subjected to an ion implantation processing to form a Ge-doped amorphous silicon layer 211. Specifically, referring to (b) in FIG. 8, the first amorphous silicon layer 212 is subjected to an ion implantation process to form a Ge-doped amorphous silicon layer 211. After forming the first amorphous silicon layer 212 and the second amorphous silicon layer 223, ion implantation is performed to realize doping of Ge, it is enabled that the doped Ge is more uniform so as to further improve the performance of the array substrate. The atomic weight of Ge is 72.59, which is much higher than the atomic weight 31/18 of phosphor (P)/boron (B), so ion implantation can be more easily controlled, and Ge can be precisely doped into the first amorphous silicon layer 212 to form the Ge-doped amorphous silicon layer 211. The second amorphous silicon layer 223 can be subjected to the laser annealing processing to form a polysilicon layer 222. Specifically, referring to (c) in FIG. 8, the second amorphous silicon layer 223 is subjected to the laser annealing processing so as to form the polysilicon layer 222.

Then, referring to (d) in FIG. 8, the Ge-doped amorphous silicon layer 211, silicon oxide layer 251 and polysilicon layer 222 are etched so as to form the light shielding layer 210, the first buffer layer 250 and the active layer 220, respectively. According to an embodiment of the disclosure, the specific way of the etching processing is not limited particularly, for example, it can be an etching process using a mask. According to an embodiment of the present disclosure, after etching, the orthographic projection of the light shielding layer 210 on the substrate 100 may include the orthographic projection of the active layer 220 on the substrate 100, thereby further improving the light shielding effect of the light shielding layer 210.

After forming the light shielding layer and the active layer, referring to (e) in FIG. 8, deposition of a gate insulating layer 400 can be performed. According to an embodiment of the present disclosure, the deposition thickness can be 500-1500 Å, and the deposited material can be SiNₓ.

According to an embodiment of the present disclosure, after forming the gate insulating layer 400, deposition of the gate 230, deposition and patterning (for forming holes) of the interlayer dielectric layer, and deposition and patterning process for the source 241 and drain 242 may be performed so as to obtain the array substrate according to the embodiments of the disclosure. The above steps may have the same features and advantages as the method descried in FIG. 7B, so they will not be elaborate herein any more.

It shall be noted that although FIGS. 7A-7B and FIG. 8 describe and illustrate in a specific order the method for manufacturing an array substrate according to the embodiments of the disclosure, embodiments of the present disclosure are not limited to the illustrated order, and other feasible orders can also be possible. For example, some steps can be performed concurrently or in an opposite order.

In the descriptions of the disclosure, directional or positional relations indicated by terms like “on/above” and “below/under” are based on the directional or positional relations as shown in the drawings, and such terms are only used for describing the disclosure, but they do not indicate that the disclosure must be constructed and operated in the specific orientations, so they shall not be construed as limiting the disclosure.

In this specification, descriptions made with reference to “an embodiment”, “another embodiment”, etc. mean that the specific features, structures, materials or characteristics described in connection with the embodiments are included in at least one embodiment of the present disclosure. In this specification, schematic expressions of the above terms are not necessarily directed to the same embodiment or example. Moreover, the described specific features, structures, materials or characteristics can be combined in appropriate ways in any one or more embodiments or examples. In addition, those skilled in the art can combine different embodiments or examples and features of different embodiments or examples described in this specification as long as no confliction is caused. Furthermore, it shall be appreciated that in this specification, the terms “first” and “second” are only used for the sake of description, but they shall not be construed as indicating or suggesting any relative importance or implicitly indicating the number of the described technical features.

Although some embodiments of the disclosure have been illustrated and described above, it shall be appreciated that they are exemplary but they do not intend to limit the disclosure. Those ordinarily skilled in the art can make changes, modifications, replacements and variations to the above embodiments without departing from the scope of the disclosure.

1. An array substrate, comprising:
a substrate;
a light shielding layer on the substrate; and
a transistor on a side of the light shielding layer away from the substrate,
wherein the transistor comprises an active layer.

2. The array substrate according to claim 1, wherein the light shielding layer comprises a Ge-doped amorphous silicon.

3. The array substrate according to claim 2, wherein the active layer comprises a low temperature polysilicon.

4. The array substrate according to claim 3, further comprising:
a first buffer layer between the active layer and the light shielding layer.

5. The array substrate according to claim 1, further comprising:
a first buffer layer between the active layer and the light shielding layer, wherein the transistor further comprises:
a source and a drain on the active layer opposite the first buffer layer, wherein the source and the drain are on a first side and a second side, respectively of a channel region in the active layer; and
a gate, wherein a first orthographic projection of the gate on the substrate at least partially overlaps a second orthographic projection of the channel region on the substrate.

6. The array substrate according to claim 2,
wherein a content of Ge in the light shielding layer comprises 0.5-5 weight percent (wt %), and
wherein the content of the Ge in the light shielding layer is dependent on a total mass of the light shielding layer.

7. The array substrate according to claim 1, further comprising:
a first buffer layer between the active layer and the light shielding layer; and
a second buffer layer between the light shielding layer and the substrate.

8. The array substrate according to claim 1, wherein a first orthographic projection of the light shielding layer on the substrate overlaps a second orthographic projection of the active layer on the substrate.

9. The array substrate according to claim 4, wherein the first buffer layer comprises SiO₂.

10. The array substrate according to claim 7, wherein the second buffer layer comprises SiNₓ.

11. A display panel, comprising the array substrate according to claim 1.

12. A display device, comprising the display panel according to claim 11.

13. A method for manufacturing an array substrate, comprising:
forming a light shielding layer on a substrate, and
forming a transistor on the light shielding layer opposite the substrate,
wherein the transistor comprises an active layer.

14. The method according to claim 13, wherein the light shielding layer comprises Ge-doped amorphous silicon.

15. The method according to claim 13, wherein the active layer comprises a low temperature polysilicon, and wherein the method further comprises:
forming a first buffer layer between the light shielding layer and the active layer.

16. The method according to claim 15, wherein the active layer is formed by operations comprising:
forming an amorphous silicon layer through chemical vapor deposition; and
performing laser annealing of the amorphous silicon layer, thereby forming the active layer.

17. (canceled)

18. The method according to claim 14, wherein the light shielding layer is formed by operations comprising:
forming an amorphous silicon material layer through chemical vapor deposition; and
adding a Ge source gas while performing the chemical vapor deposition.

19. The method according to claim 14, wherein the light shielding layer is formed by operations comprising:
forming an amorphous silicon material layer through chemical vapor deposition; and
doping Ge into the amorphous silicon material layer through ion implantation.

20. The method according to claim 13, wherein the method further comprises:
forming a second buffer layer on the substrate before forming the light shielding layer.

21. The method according to claim 13, further comprising:
forming a source and a drain on the active layer opposite the substrate, wherein the source and the drain are on a first side and second side, respectively, of a channel region in the active layer; and
forming a gate on the active layer opposite the substrate,
wherein a first orthographic projection of the gate on the substrate at least partially overlaps a second orthographic projection of the channel region on the substrate.
